(19) United States
(12) Patent Application Publication
(10) Pub. No.: US 2017/0125380 A1
(43) Pub. Date: May 4, 2017

(54) INTER-CHIP CONNECTION FOR NOISE MITIGATION

(71) Applicant: SAMSUNG DISPLAY CO., LTD., Yongin-City (KR)

(72) Inventor: Minghui Han, San Jose, CA (US)

(21) Appl. No.: 14/929,051

(22) Filed: Oct. 30, 2015

(51) Int. Cl. H01L 25/065; H01L 25/00; H01L 23/538; H01L 23/66

(52) U.S. Cl. CPC H01L 25/0655; H01L 23/66; H01L 25/50; H01L 23/5386; H01L 2223/6627; H01L 2223/6611

(57) ABSTRACT

There is provided an inter-chip power connection in a multi-chip system, the inter-chip power connection including a transmission line connecting a first on-die power grid of a first die to a second on-die power grid of a second die, the first and second dies sharing a same first conductive layer supplying a power voltage of a power supply, wherein the transmission line is not directly connected to the first conductive layer.

### FIELD

Aspects of the present invention relate to the field of power distribution, and particularly to mitigation of power supply noise in a power delivery network.

### BACKGROUND

As the design and layout of semiconductor chips become more complex, and operational frequencies and the use of supply voltage scaling increase, there is an ever increasing need to mitigate undesired noise in the chip design. A chip's power distribution network (PDN) is a major noise source as fluctuations in supply voltage resulting from high frequency signaling in the presence of network parasitic resistance, inductance, and capacitance alter signals' voltage levels can cause errors in the chip's operation. Thus, designing a robust PDN with low dynamic noise has become a challenge.

Static voltage drop is commonly addressed through reduction of series resistance (e.g., increased metallization), and pad placement and general topology optimization. For limiting dynamic voltage fluctuations in a power network, the main technique is to place one or more decoupling capacitors near power supply regions and other noise sources. Other mitigation techniques include reducing package inductance, and the like. However, these and other techniques have their limitations. For example, die area constraint limits the maximum amount of on-die decoupling capacitance available to designers, pin count constraint limits the minimum parasitic inductance achievable for power supplies in a chip package, and embedded capacitors and inductors increase cost and complexity.

What is desired is a new method and architecture for suppressing dynamic power noise in an electronic system.

### SUMMARY

Aspects of embodiments of the invention are directed toward improving noise performance through modifying the connection of power distribution network (PDN) resources among different chips in a system containing multiple chips, such as multi-processor hardware platforms, memory modules, source PCBs of display panels, and or the like. Thus, rather than improve PDN resources inside each individual chip, embodiments of the present invention improve the sharing of PDN resources among multiple chips.

According to some embodiments of the invention, there is provided an inter-chip power connection in a multi-chip system, the inter-chip power connection including: a transmission line connecting a first on-die power grid of a first die to a second on-die power grid of a second die, the first and second dies sharing a same first conductive layer supplying a power voltage of a power supply, wherein the transmission line is not directly connected to the first conductive layer.

In an embodiment, the transmission line passes through packages of the first and second dies to connect a first package electrode of the first die to a second package electrode of the second die, wherein the first and second package electrodes are wire bonded to the first and second dies.

In an embodiment, the transmission line includes a microstrip or a stripline PCB trace.

In an embodiment, the transmission line is configured to suppress power noise at a frequency range corresponding to a dominant power noise of the first and second on-die power grids.

In an embodiment, a length of the transmission line corresponds to the frequency range of the suppressed power noise.

In an embodiment, a characteristic impedance of the transmission line is 50 ohms.

In an embodiment, the first and second dies share a same second conductive layer, the second conductive layer being at a ground voltage, and the transmission line is not directly connected to the second conductive layer.

In an embodiment, each of the first and second conductive layers include a metal plane.

In an embodiment, the transmission line connects a first ground network of the first on-die power grid to a second ground network of the second on-die power grid.

In an embodiment, the transmission line connects a first power network of the first on-die power grid to a second power network of the second on-die power grid.

In an embodiment, the transmission line includes a plurality of transmission lines configured to suppress power noise at a plurality of frequency ranges.

In an embodiment, lengths of the plurality of transmission lines correspond to the plurality of frequency ranges of the suppressed power noise.

According to some embodiments of the invention, there is provided a power distribution network for distributing power to a plurality of dies sharing a same conductive layer supplying a power voltage of a power supply, the power distribution network including: a plurality of transmission lines connecting on-die power grids of the plurality of dies, the plurality of transmission lines being not directly connected to the conductive layer.

In an embodiment, the plurality of transmission lines connect the on-die power grids of the plurality of dies in a linear chain.

In an embodiment, the plurality of transmission lines connect the on-die power grids of the plurality of dies in a ring formation.

In an embodiment, the plurality of transmission lines connect the on-die power grids of the plurality of dies in a mesh structure.

In an embodiment, the plurality of transmission lines pass through packages of the plurality of dies to connect a plurality of package electrodes of the plurality of dies to one another, and the plurality of package electrodes are wire bonded to corresponding ones of the plurality of dies.

In an embodiment, the plurality of transmission lines connects a plurality of power pads of the on-die power grids of the plurality of dies to one another.

According to some embodiments of the invention, there is provided a method of mitigating power noise in a multi-chip system, the method including: providing a first die having a first on-die power grid and a second die having a second on-die power grid, the first and second dies sharing a same first conductive layer supplying a power voltage of a power supply, and connecting the first on-die power grid to the second on-die power grid with a transmission line not directly connected to the first conductive layer, wherein the transmission line is configured to suppress power noise at a frequency range corresponding to a dominant power noise of the first and second on-die power grids.

In an embodiment, the transmission line connects a first power network of the first on-die power grid to a second power network of the second on-die power grid.

### BRIEF DESCRIPTION OF THE DRAWINGS

The accompanying drawings, together with the specification, illustrate exemplary embodiments of the invention, and, together with the description, serve to explain aspects of embodiments of the invention. In the drawings, like reference numerals are used throughout the figures to reference like features and components. The figures are not necessarily drawn to scale. The above and other features and aspects of the invention will become more apparent by the following detailed description of illustrative embodiments thereof with reference to the attached drawings, in which:

FIG. 1A is a schematic diagram illustrating an inter-chip power connection scheme in an electronic system utilizing a wire-bond configuration, according to some exemplary embodiments of the present invention; FIG. 1B is a schematic diagram illustrating an inter-chip power connection scheme in an electronic system utilizing a flip-chip configuration, according to some exemplary embodiments of the present invention;

FIG. 2 is a schematic diagram illustrating an equivalent circuit model of the power distribution network of the electronic systems and of FIGS. 1, according to some exemplary embodiments of the present invention;

FIGS. 3A-3C compare the noise performance of an electronic system utilizing a transmission line and that of the electronic system lacking the transmission line, according to some exemplary embodiments of the present invention;

FIG. 4 is a block diagram illustrating an electronic system utilizing a plurality of transmission lines, according to some exemplary embodiments of the present invention; and

FIGS. 5A-5C are block diagrams illustrating different configurations of a power distribution network in an electronic system, according to some exemplary embodiments of the present invention.

### DETAILED DESCRIPTION

In an electronic system, when multiple chips share the same power or ground network, the corresponding inter-chip electrical connection is realized through shared metal planes on a printed circuit board (PCB). According to aspects of the present invention, there is an extra inter-chip electrical connection path for the shared power or ground network, which is realized through one or more dedicated transmission lines (e.g. microstrips or striplines) on the PCB that link the on-die power distribution networks (PDNs) of the chips.

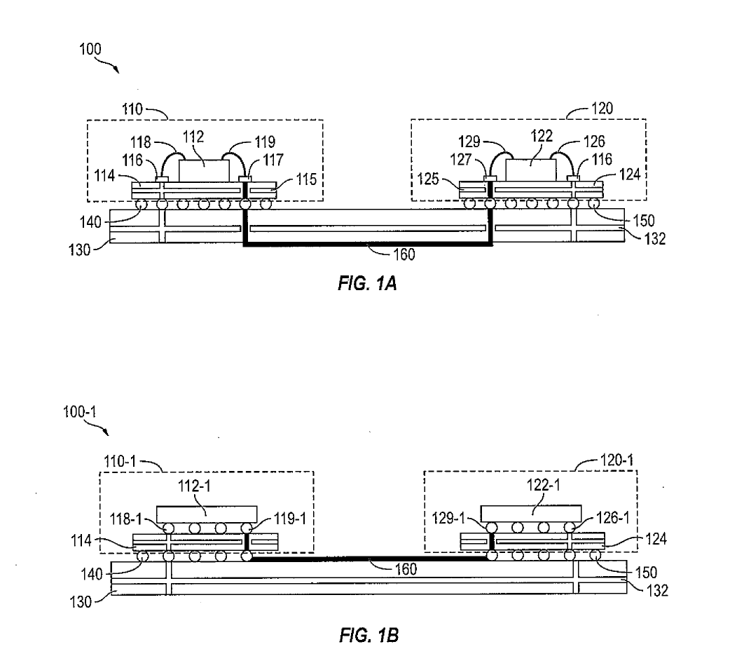

FIG. 1A is a schematic diagram illustrating an inter-chip power connection scheme in an electronic system 100 utilizing a wire-bond configuration, according to some exemplary embodiments of the present invention.

Referring to FIG. 1A, the electronic system 100 includes a first chip 110 and a second chip 120 coupled to a printed circuit board (PCB) 130 via first protrusions (e.g., first solder bumps) 140 and second protrusions (e.g., second solder bumps) 150, respectively. The first chip 110 includes a first die 112, a first package 114, and the second chip 120 includes a second die 122 and a second package 124.

The PCB 130 supplies the two chips 110 and 120 with the same power supply via a shared conductive layer (e.g., a metal power plane) 132 embedded within, or at a surface of, the PCB 130. The shared conductive layer may be coupled to a DC power supply or a DC-DC power regulator supplying a power voltage VDD. The conductive layer 132 may be electrically coupled to the first on-die power grid (e.g., a first on-chip PDN) of the first die 112 via one or more of the first protrusions 140, a first connector 115 within the first package 114, a first bonding pad 116 fixedly coupled to the first package 114, and a first bonding wire 118 connecting the first bonding pad 116 and the first on-die power grid of the first die 112. In a similar manner, the conductive layer 132 may be electrically coupled to the second on-die power grid (e.g., a second on-chip PDN) of the second die 122 via one or more of the second protrusions 150, a second connector 125 within the second package 124, a second bonding pad 126 fixedly coupled to the second package 124, and a second bonding wire 128 connecting the second bonding pad 126 and the second on-die power grid of the second die 122. Thus, the conductive layer 132 may supply a voltage of about VDD to the power supply networks of the first and second on-die power grids.

The first connector 115 may be a simple wire-connection or, as shown in FIG. 1A, may be a conductive plane embedded within the first and second packages 114 and 124.

According to some embodiments, the inter-chip power connection includes a transmission line 160 connecting the on-die power grids of the first and second dies 112 and 122. The transmission line 160 forms an electron flow path that is not directly connected to, and is physically separate from, the conductive layer 132. The transmission line 160 may pass through the first package 114 along a path physically separate from the first connector 115, and connect to a first auxiliary bonding pad 117 of the first package 114, which is connected to the on-die power grid of the first die 112 through a first auxiliary bond wire 119. In a similar manner, the transmission line 160 may pass through the second package 124 along a path physically separate from the second connector 125, and connect to a second auxiliary bonding pad 127 of the second package 124, which is connected to the on-die power grid of the second die 122 through a second auxiliary bond wire 129.

In some examples, the transmission line 160 may be a microstrip or a stripline PCB trace. As is illustrated in FIG. 1A, the transmission line 160 may Pass through the PCB 130 without contacting the conductive layer 132 and be substantially located at a side of the PCB 130 opposite from the first and second chips 110 and 120. However, embodiments of the present invention are not limited thereto. For example, the transmission line may be located at the same side of the PCB 130 as the first and second chips 110 and 120, or be at least partially embedded within the PCB 130.

While, in the examples of FIG. 1A, the first and second packages 114 and 124 do not fully encapsulate the first and second dies 112 and 122, respectively, embodiments of the present invention are not limited thereto. For examples, the first and second packages 114 and 124 may be configured to fully surround or encapsulate the first and second dies 112 and 122, and to isolate the first and second dies 112 and 122 from the external environment.

FIG. 1B is a schematic diagram illustrating an inter-chip power connection scheme in an electronic system 100-1 utilizing a flip-chip configuration, according to some exemplary embodiments of the present invention.

Referring to FIG. 1B, in some examples, the first and second chips 110-1 and 120-1 may be bonded to the PCB 130 through a flip-chip configuration. That is, rather than use bonding wires 118 and 119 to connect the first and second dies 112-1 and 122-1 to the first and second packages 114 and 124, the dies 112-1 and 122-1 may be flipped (e.g., positioned upside down) and the electrodes of the first and second dies 110-1 and 120-1 may be directly bonded to (e.g., directly soldered to) the first and second packages 114 and 124 via protrusions, such as the first and second power protrusions 118-1 and 128-1 and the first and second auxiliary protrusions 119-1 and 129-1. The conductive layer 132 within the PCB 130 may connect to the on-die power grid of the first die 112-1 through one or more of the first protrusions 140, and to the on-die power grid of the second die 122-1 through one or more of the second protrusions 150.

According to some embodiments; the transmission line 160 may connect the on-die power grids of the first and second dies 112-1 and 122-1 through respective ones of the first and second protrusions 140 and 150. As described above with reference to FIG. 1A, the transmission line 160 may be a microstip or stripline PCB trace located at a same side of the PCB 130 as the first and second dies 112-1 and 122-1 (as shown in FIG. 1B), or may be at any other suitable location based on PCB layout restrictions and the characteristics of the transmission line 160. For example, the transmission line 160 may pass through the PCB without contacting the conductive layer 132 and be positioned at the other side of the PCB 130 (as shown in FIG. 1A), or be substantially embedded within the PCB 130.

While FIGS. 1A-1B illustrate embodiments in which the transmission line 160 links the power networks of the on-die power grids of chips 110 and 120, embodiments of the present invention are not limited thereto. For example, the transmission line 160 may act as a complimentary inter-chip ground connection. That is, in some embodiments, the transmission line 160 may link the ground networks of the on-die power grids of the first and second chips 110 and 120 in a manner substantially similar to that described above with reference to FIGS. 1A-1B. In such embodiments, the transmission line 160 may not be directly connected to, and be physically separated from, the common ground layer (e.g., common ground layer) in the PCB 130 that is shared by both the first and second chips 110 and 120.

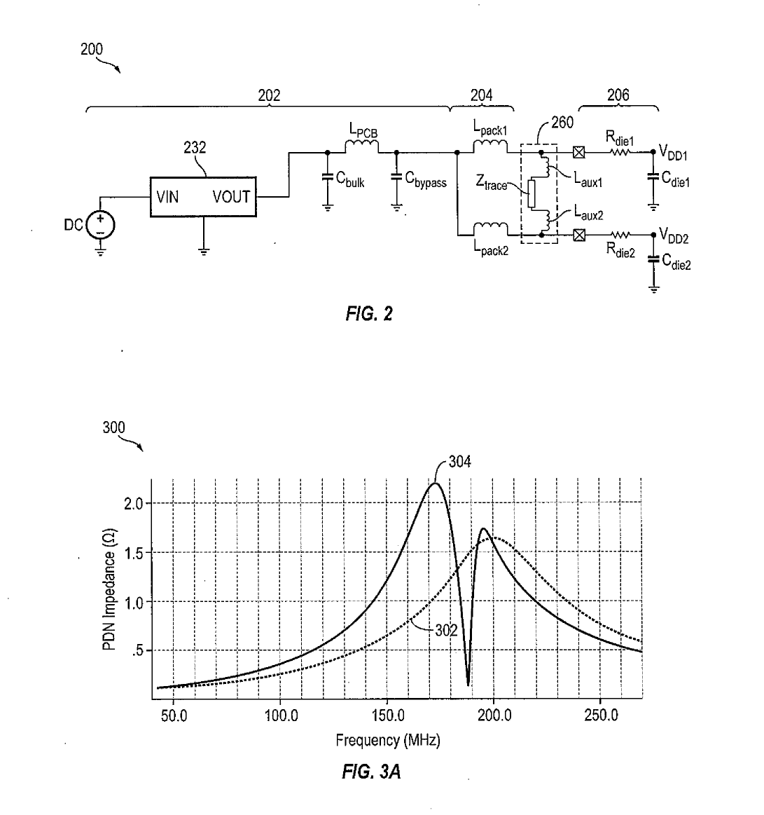

FIG. 2 is a schematic diagram illustrating an equivalent circuit model 200 of the power distribution network of the electronic systems 100 and 100-1 of FIGS. 1A, according to some exemplary embodiments of the present invention.

Referring to FIG. 2, section 202 is the equivalent circuit representation of the PCB 130 and includes the power supply (e.g., DC-DC regulator) 232, the bulk capacitor C_{bulk}, which represents the large capacitances near the power supply 232, the PCB inductance L_{PCB}, which represents the total inductance of the PCB 130, and bypass capacitance C_{bypass}, which represents the bypass capacitors near the first and second chips 110 and 120 (or 110-1 and 120-1). Section 204 represents the equivalent circuit of the first package 114 and the second package 124, which may be respectively modeled as the first package inductance L_{pack1} and the second package inductance L_{pack2}. The first and second package inductances L_{pack1} and L_{pack2} are the equivalent inductance between the power network of the on-die power grids of first and second dies 112 and 122 (or 112-1 and 122-1), respectively, and the ground plane in the PCB 130. Section 206 represents the equivalent circuit of the first and second dies 112 and 122 (or 112-1 and 122-1) and includes a first resistance R_{die1}, which represents the on-die power grid resistance of the first die 112 (or 112-1), and a first capacitance C_{die1}, which represents the bypass capacitances inside the first die 112 (or 112-1). The second section further includes a second resistance R_{die2} and a second capacitance C_{die2} of the second die 122 (or 122-1), which are representationally similar to a first resistance R_{die1} and C_{die1}. In FIG. 2, V_{DD1} and V_{DD2} represent the voltage of the on-die power grids of the first and second dies 112 and 122 (or 112-1 and 122-1).

According to some embodiments (e.g., the embodiments of FIG. 1A), the transmission line 160 may be modeled as a circuit 260 that includes an inductance Lₐᵤₓ₁, which represents the inductance of the first auxiliary bonding wire 119 (of, e.g., FIG. 1A) or the first auxiliary protrusion 119-1 (of, e.g., FIG. 1B) of the first dies 112 or 112-1, and a corresponding inductance Lₐᵤₓ₂ of the second die 122 (of, e.g., FIG. 1A) or 122-1 (of, e.g.; FIG. 1B). The model circuit 260 further includes the transmission impedance Z_{trace} that represents the effective impedance of the transmission line 160.

In some examples, the values of the inductances L_{pack1}, L_{pack2}, Lₐᵤₓ₁, and Lₐᵤₓ₂ may be lower in the embodiments of FIG. 1B than in the embodiments of FIG. 1A.

As illustrated by the equivalent circuit model 200, as a result of the transmission line 160 between the first and second dies 112 and 122 (or 112-1 and 122-1), the on-die power grids of the first and second dies 112 and 122 (or 112-1 and 122-1) have a connection path that largely bypasses the impact of package and PCB PDN components. As a result, the power supply noise level inside one chip may be affected much more significantly by the presence of the other chip.

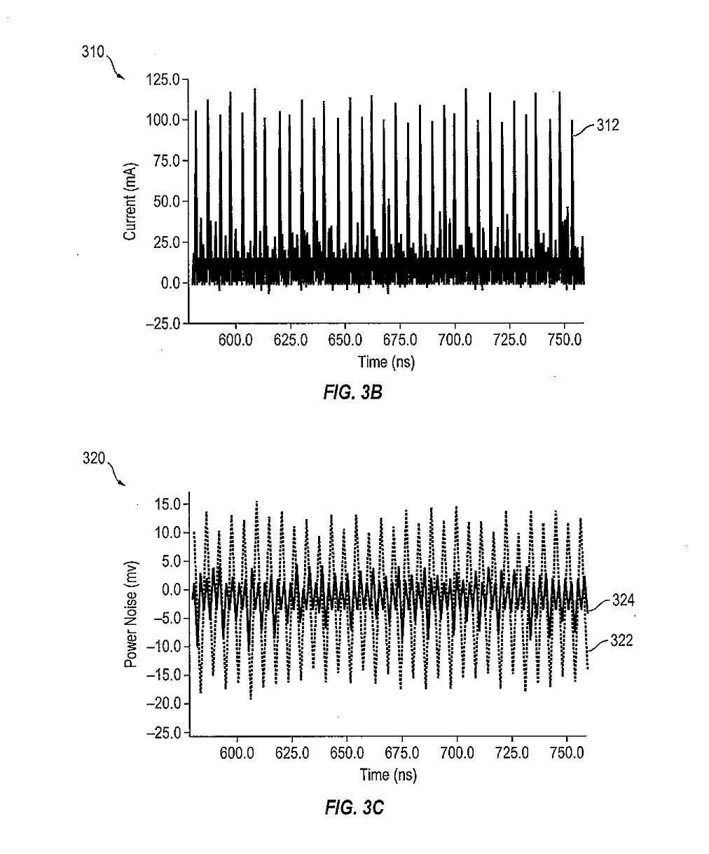

FIGS. 3A-3C compare the noise performance of the electronic system 100 utilizing the transmission line 160 and that of the electronic system 100 in the absence of the transmission line 160, according to some exemplary embodiments of the present invention. FIG. 3A is a diagram 300 illustrating the PDN impedance of the electronic system 100 of FIG. 1A, according to some exemplary embodiments of the present invention. FIG. 3B is a diagram 310 illustrating the current waveform of the on-die power grid in time domain, according to some exemplary embodiments of the present invention. FIG. 3C is a diagram 320 illustrating the power noise waveform of the electronic system 100 in time domain, according to some exemplary embodiments of the present invention.

In the embodiments of FIGS. 3A-3C, the first and second chips 110 and 120 are substantially identical and share a common power supply voltage through the conductive layer 132.

Referring to FIG. 3A, the curve 302 represents the PDN impedance of the electronic system 100 in the absence of the transmission line 160, and curve 304 represents the PDN impedance of the electronic system 100 utilizing the transmission line 160. The PDN impedance represented by curves 302 and 304 measures, at any given frequency, how much on-die power noise (e.g., VDD noise) is generated in each chip when both of the first and second chips 110 and 120 draw the same amount of current from the power supply.

As is shown by curve 302, in the absence of the transmission line 160, the PDN impedance of on-die power grid observed inside each of the first and second chips 110 and 120 has a conventional resonance shape in the frequency domain, with a resonance peak frequency at about 200 MHz and a peak impedance value of about 1.6Ω.

As is shown by curve 304, in the presence of the transmission line-like communication channel between on-die power grids of the first and second chips 110 and 120, that is, the transmission line 160, a sharp dip is created in the power grid's PDN impedance curve for both chips 110 and 120. In the Example of the diagram 300, the propagation delay of the transmission line 160 is chosen to be about 2.62 ns, so that the dip occurs near the resonance peak frequency, that is, about 188 MHz.

Referring to FIG. 3B, the waveform 312 represents the time-domain waveform of on-die power grid current in each of the chips 110 and 120 in examples in which the electronic system 100 does not utilize the transmission line 160. As is shown, the current waveform 312 exhibits a strong frequency component near the resonance peak frequency of about 188 MHz.

Referring to FIG. 3C, the waveform 322 represents the power noise (e.g., VDD noise) waveform in each of the chips 110 and 120 in the absence of the transmission line 160. As in the current waveform 312 of FIG. 3B, the power noise waveform 322 also shows a strong frequency component near the resonance peak frequency of about 188 MHz. Waveform 324 represents the power noise waveform in each of the chips 110 and 120 in embodiments in which the electronic system 100 utilizes the transmission line 160. The power noise waveform 324 indicates (as also shown by curve 304 of FIG. 3A) that when the transmission line 160 is used to provide an alternative connection between the on-die power grids of the first and second dies 112 and 122, the noise component near 188 MHz is largely suppressed, which also leads to a reduction in the total noise (peak-to-peak) of about 55% as compared to the example of waveform 322.

While in the examples of FIGS. 3A-3B, the transmission line was used to suppress power noise at about 188 MHz, embodiments of the present invention are not limited thereto. That is, according to embodiments of the present invention, the transmission line may be designed to suppress power noise at a particular frequency or frequency range, which corresponds to a dominant noise of the on-die power grids of the first and second dies 112 and 122 (or 112-1 and 122-1). The suppression frequency may be adjusted based on the length, cross-sectional profile (e.g., width), and/or shape of the transmission line (e.g., micro strip or stripline) 160 to optimize performance.

The characteristic impedance of the transmission line may be designed to be about 50Ω; however, embodiments of the present invention are not limited thereto, and the characteristic impedance may assume any suitable value.

The approach to dynamic noise suppression described above, does not consider each chip of an electronic system in isolation. Rather, it utilizes the PDN resources in one chip to improve power noise performance in another chip. Embodiments of the present invention include a transmission-like trace (e.g., a microstrip or stripine) connected between on-die power grids of different chips to suppress power noise at particular frequencies. The transmission line acts as an alternative inter-chip connection to that achieved through shared power/ground planes on a PCB.

In some examples, the on-die PDN current may have several dominant frequencies. Therefore, being able to suppress power noise at those dominant frequencies through appropriately designed inter-chip power/ground traces can be very effective in mitigating the overall impact of power noise.

FIG. 4 is a block diagram illustrating an electronic system 100-2 utilizing a plurality of transmission lines, according to some exemplary embodiments of the present invention. For convenience of illustration, the PCB and the means for coupling the chips 110 and 120 to the PCB are not shown.

Referring to FIG. 4, the on-die power grids of the first and second chips 110 and 120 of the electronic system 100-2 may be coupled to one another via a plurality of transmission lines 162 including, for example, the first through third transmission lines 162, 164, and 166. Each of the plurality of transmission lines 162 may be substantially the same as the transmission line 160 of FIGS. 1A-1B; therefore, a description thereof may not be repeated hereafter.

According to some embodiments, one or more of the plurality of transmission lines 162 may connect the on-die power supplies (e.g., VDD) of the chips 110 and 120. Furthermore, one or more of the plurality of transmission lines 162 may connect the on-die grounds of the chips 110 and 120. The plurality of transmission lines 162 may not be directly connected to the power or ground planes of the PCB.

In some embodiments, the plurality of transmission lines may have different lengths corresponding to various dominant frequencies of the electronic system 100-2. Thus, the plurality of transmission lines may effectively suppress the dominant power noise frequencies of the on-die power grids of the chips 110 and 120.

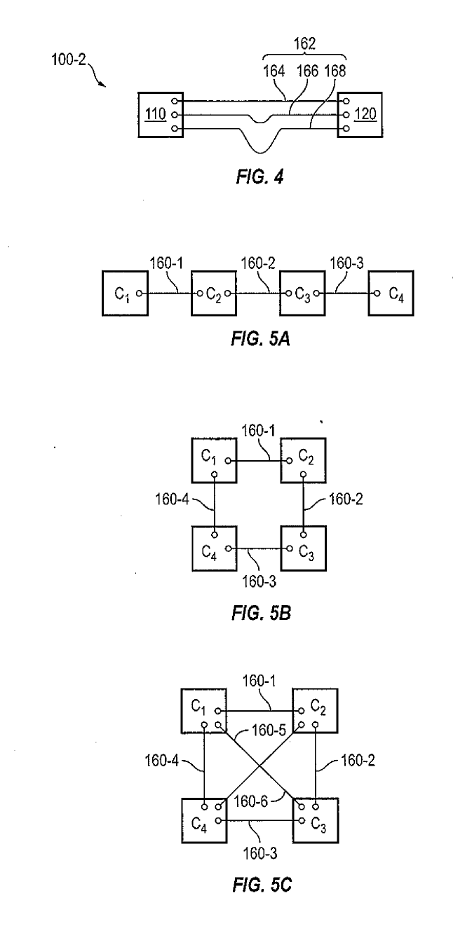

FIGS. 5A-5C are block diagrams illustrating different configurations of a power distribution network in an electronic system, according to some exemplary embodiments of the present invention. For convenience of illustration, in FIGS. 5A to 5C, the PCB and the means for coupling the plurality of chips C₁-C₄ to the PCB are not shown. Further, in each of the electronic systems 100-3 to 100-5, only four chips C₁-C₄ are shown; however, this is only for illustration purposes, and each of the electronic systems 100-3 to 100-5 may include any suitable number of chips.

As shown in FIG. 5A, according to some embodiments of the present invention, a plurality of transmission lines 160-1 to 160-3 may serially connect the on-die power grids of the plurality chips C₁-C₄ in a linear chain, where adjacent ones of the plurality of chips C₁-C₄ are linked together by a corresponding one of the transmission lines 160-1 to 160-3, and the chips at the ends of the linear chain are not connected via any transmission lines.

As shown in FIG. 5B, according to some embodiments of the present invention, a plurality of transmission lines 160-1 to 160-4 may serially connect the on-die power grids of the plurality chips C₁-C₄ in a ring formation, where every one of the plurality of chips C₁-C₄ are linked to a preceding and subsequent chip via corresponding ones of the transmission lines 160-1 to 160-4.

As shown in FIG. 5B, according to some embodiments of the present invention, a plurality of transmission lines 160-1 to 160-4 may connect the on-die power grids of the plurality chips C₁-C₄ in a ring formation, where every one of the plurality of chips C₁-C₄ are linked to a preceding chip and a subsequent chip via corresponding ones of the transmission lines 160-1 to 160-4.

As shown in FIG. 5C, according to some embodiments of the present invention, a plurality of transmission lines 160-1 to 160-6 may connect the on-die power grids of the plurality chips C₁-C₄ in a mesh structure, where each of the plurality of chips C₁-C₄ is linked to one or more of the plurality of chips C₁-C₄ via corresponding ones of the transmission lines 160-1 to 160-6. In some examples, each of the plurality of chips C₁-C₄ may be linked to every other one of the plurality of chips C₁-C₄.

In the embodiments of FIGS. 5A-5C, each of the plurality of chips C₁-C₄ may be the same; however, embodiments of the present invention are not limited thereto, and one or more of the plurality of chips C₁-C₄ may be different from the other chip. In some examples, the transmission lines in FIGS. 5A-5C may have the same lengths and cross-sectional profiles (e.g., widths). In other examples, the length and cross-sectional profile of one or more of the transmission lines may be different from the other transmission lines.

As will be understood by a person of ordinary skill in the art, embodiments of the present invention are not limited to the configurations illustrated in FIGS. 5A-5C, and the plurality of chips in an electronic system may be connected to one another via transmission lines using any suitable configuration.

The transmission line according to embodiments of the present invention may be utilized in any electronic system that has two or more similar chips, such as a memory module, a display panel's source PCB that connects to multiple driver integrated circuits (ICs), and/or the like.

While this invention has been described in detail with particular references to illustrative embodiments thereof, the embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention, as set forth in the following claims and equivalents thereof.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the inventive concept.” Also, the term “exemplary” is intended to refer to an example or illustration.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

1. An inter-chip power connection in a multi-chip system, the inter-chip power connection comprising:
a transmission line connecting a first on-die power grid of a first die to a second on-die power grid of a second die, the first and second dies sharing a same first conductive layer supplying a power voltage of a power supply, the first and second dies being arranged on a printed circuit board (PCB) and footprints of the first and second dies on the PCB being laterally separate from one another,
wherein the transmission line is not directly connected to the first conductive layer.

2. The inter-chip power connection of claim 1,
wherein the transmission line passes through packages of the first and second dies to connect a first package electrode of the first die to a second package electrode of the second die, and
wherein the first and scond package electrodes are wire bonded to the first and second dies.

3. The inter-chip power connection of claim 1, wherein the transmission line comprises a microstrip or a stripline PCB trace.

4. The inter-chip power connection of claim 1, wherein the transmission line is configured to suppress power noise at a frequency range corresponding to a dominant power noise of the first and second on-die power grids.

5. The inter-chip power connection of claim 4, wherein a length of the transmission line corresponds to the frequency range of the suppressed power noise.

6. The inter-chip power connection of claim 1, wherein a characteristic impedance of the transmission line is 50 ohms.

7. The inter-chip power connection of claim 1,
wherein the first and second dies share a same second conductive layer, the second conductive layer being at a ground voltage, and
wherein the transmission line is not directly connected to the second conductive layer.

8. The inter-chip power connection of claim 7, wherein each of the first and second conductive layers comprise a metal plane.

9. The inter-chip power connection of claim 7, wherein the transmission line connects a first ground network of the first on-die power grid to a second ground network of the second on-die power grid.

10. The inter-chip power connection of claim 1, wherein the transmission line connects a first power network of the first on-die power grid to a second power network of the second on-die power grid.

11. The inter-chip power connection of claim 1, wherein the transmission line comprises a plurality of transmission lines configured to suppress power noise at a plurality of frequency ranges.

12. The inter-chip power connection of claim 11, wherein lengths of the plurality of transmission lines correspond to the plurality of frequency ranges of the suppressed power noise.

13. A power distribution network for distributing power to a plurality of dies sharing a same conductive layer supplying a power voltage of a power supply, the power distribution network comprising:
a plurality of transmission lines connecting on-die power grids of the plurality of dies, the plurality of transmission lines being not directly connected to the conductive layer, wherein footprints of the plurality of dies on a printed circuit board (PCB), on which the plurality of dies are arranged, are laterally separate from one another.

14. The power distribution network of claim 13, wherein the plurality of transmission lines connect the on-die power grids of the plurality of dies in a linear chain.

15. The power distribution network of claim 13, wherein the plurality of transmission lines connect the on-die power grids of the plurality of dies in a ring formation.

16. The power distribution network of claim 13, wherein the plurality of transmission lines connect the on-die power grids of the plurality of dies in a mesh structure.

17. The power distribution network of claim 13,
wherein the plurality of transmission lines pass through packages of the plurality of dies to connect a plurality of package electrodes of the plurality of dies to one another, and
wherein plurality of package electrodes are wire bonded to corresponding ones of the plurality of dies.

18. The power distribution network of claim 13, wherein the plurality of transmission lines connects a plurality of power pads of the on-die power grids of the plurality of dies to one another.

19. A method of mitigating power noise in a multi-chip system, the method comprising:
providing a first die having a first on-die power grid and a second die having a second on-die power grid, the first and second dies sharing a same first conductive layer supplying a power voltage of a power supply, the first and second dies being arranged on a printed circuit board (PCB) and footprints of the first and second dies on the PCB being laterally separate from one another, and
connecting the first on-die power grid to the second on-die power grid with a transmission line not directly connected to the first conductive layer,
wherein the transmission line is configured to suppress power noise at a frequency range corresponding to a dominant power noise of the first and second on-die power grids.

20. The inter-chip power connection of claim 19, wherein the transmission line connects a first power network of the first on-die power grid to a second power network of the second on-die power grid.
